(19) United States
(12) Patent Application Publication
(10) Pub. No.: US 2006/0138459 A1
(43) Pub. Date: Jun. 29, 2006

(54) Semiconductor device, manufacturing method of the same and electronic device

(76) Inventors: Atsushi Kurokawa, Takasaki (JP); Isao Ohbu, Sagamihara (JP); Yasunari Umemoto, Sayama (JP); Satoshi Sasaki, Takasaki (JP); Chushiro Kusano, Niiza (JP); Yoshinori Imamura, Sagamiko (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/316,989

(22) Filed: Dec. 27, 2005

(30) Foreign Application Priority Data
Dec. 27, 2004 (JP) 2004-375632

(51) Int. Cl. H01L 31/109

(52) U.S. Cl. 257/197

(57) ABSTRACT

Provided is a semiconductor device equipped with HBTs capable of satisfying both thermal stability and reliability and having improved electrostatic breakdown voltage.

The HBT according to the present invention is obtained by successively forming, over the main surface of a substrate made of a compound semiconductor, a sub-collector layer, a collector layer, a base layer, an emitter layer, a collector electrode electrically connected to the collector layer, a base electrode electrically connected to the base layer, an emitter mesa layer formed over the emitter layer and electrically connected to the emitter layer, and an emitter electrode electrically connected to the emitter mesa layer. The emitter mesa layer has a semiconductor layer made of an n type GaAs layer, a high concentration semiconductor layer made of an n⁺ type GaAs layer over the semiconductor layer and a ballast resistor layer made of an n type InGaAs layer over the high concentration semiconductor layer.

### CROSS-REFERENCE TO RELATED APPLICATION

The present application claims priority from Japanese patent application No. 2004-375632 filed on Dec. 27, 2004, the content of which is hereby incorporated by reference into this application.

### BACKGROUND OF THE INVENTION

The present invention relates to a semiconductor device and a manufacturing technology thereof, in particular, to a technology effective when applied to a hetero-junction bipolar transistor (which will hereinafter be abbreviated as “HBT”). Further, the present invention pertains to an electronic device using it.

In recent years, with rapid growth of demand of wireless communications equipment, research and development on a power amplifier used for the communications equipment has been carried out intensively. Examples of semiconductor transistors used for a power amplifier for mobile communications equipment include HBT, field effect transistor and silicon (Si)-MOSFET (Metal Oxide Semiconductor Field Effect Transistor) Among them, the HBT serves as a leading transistor for a power amplifier for mobile communications equipment because it is characterized in that it is excellent in linearity of an input/output characteristic, can be operated only by a positive power source, dispenses with a circuit or part for generating a negative power source, has a high output power density, and needs only a small chip area and therefore is labor saving and low cost.

The HBT has however a heat-induced instable operation phenomenon which is called thermal runaway. In order to stabilize its operation, so-called ballast resistor which is a stabilizing resistor is therefore used. In Table 1 of Re-published Patent WO 98/53502, a technology using an AlGaAs ballast resistor layer stacked over an InGaP emitter layer as means for actualizing the stabilization is shown.

### SUMMARY OF THE INVENTION

The present inventors have developed an RF (Radio Frequency) power amplifier module (electronic device) to be used for wireless communications equipment. During this development, the present inventors have found two problems relating to an HBT for an RF power amplifier module.

The first problem is that the conventional technology, for example, the technology as disclosed in WO98/53502, has trouble in the reliability of power distribution of an HBT. The present inventors have found that an HBT having a structure containing the above-described AlGaAs ballast resistor layer causes a severe deterioration in properties during power distribution.

In order to identify causes for the deterioration of properties of an HBT having a structure containing a ballast resistor layer during power distribution, the present inventors manufactured HBTs different in cross-sectional structure as illustrated in FIGS. 23 and 24 and compared the reliability between these HBTs.

FIG. 23 is a schematic cross-sectional view of an HBT having a ballast-resistor-layer-containing structure investigated by the present inventors. The HBT has a layered structure obtained by successively stacking, over a substrate 101 made of a semi-insulating GaAs layer, a sub-collector layer 102 made of an n type GaAs layer, a collector layer 103 made of an n type GaAs layer, a base layer 104 made of a p type GaAs layer, an emitter layer 105 made of an n type InGaP layer, a ballast resistor layer 107 made of an n type AlGaAs layer, a contact layer 108 made of an n type GaAs layer, and a contact layer 109 made of an n type InGaAs layer. In FIG. 23, designated by 111, 112 and 113 are collector electrode, base electrode and emitter electrode, respectively.

FIG. 24 is a schematic cross-sectional view of an HBT having a ballast-resistor-layer-free structure investigated by the present inventors for comparison with the HBT having the structure as illustrated in FIG. 23. It has a layered structure obtained by successively stacking, over a substrate 101 made of a semi-insulating GaAs layer, a sub-collector layer 102 made of an n type GaAs layer, a collector layer 103 made of an n type GaAs layer, a base layer 104 made of a p type GaAs layer, an emitter layer 105 made of an n type InGaP layer, a semiconductor layer 106 made of an n type GaAs layer, a contact layer 108 made of an n type GaAs layer and a contact layer made of an n type InGaAs layer one after another. In FIG. 24, designated by 111, 112 114 are collector electrode, base electrode and emitter electrode, respectively.

A power distribution test was conducted on the HBTs as illustrated in FIGS. 23 and 24 for 300 hours under the same conditions of a collector current density of 40 kA/cm² and a junction temperature of 210° C. As a result of the test made on 20 HBTs each illustrated in FIG. 23 and having a structure containing a ballast resistor layer 107 over an emitter layer 105, all of them showed deterioration. The power distribution test was also made on 20 HBTs each illustrated in FIG. 24 and having a ballast-resistor-layer-free structure, but no HBT exhibited deterioration.

From the above-described results of the reliability comparison, a reason why the HBT having a ballast resistor layer made of an AlGaAs layer right above an emitter layer made of an InGaP layer has a short element life is presumed to be identified as follows: in general, recombination of holes and electrons tend to occur at a recombination center in a depletion layer compared with that in a neutral region. Most of the holes injected from a base are therefore recombined in the depletion layer of an emitter. Since a large number of deep impurity levels such as DX centers exist in AlGaAs, they act as a nonradiative recombination center. Based on them, it is presumed that when holes adversely injected from a base layer made of a p type GaAs layer to the side of an emitter layer made of an n type InGaP layer reach a ballast resistor layer made of an AlGaAs layer by diffusion, the diffused holes are recombined with electrons via impurity levels such as DX centers and the energy released at this time proliferates lattice defects, leading to a deterioration in element. In short, an accelerated increase in the recombination current increases a base current, which is presumed to lead to a decrease (deterioration) in h_{FE}.

It is therefore effective to prevent depletion of a ballast resistor layer made of an AlGaAs layer having many recombination centers such as DX centers in order to improve reliability of the power distribution of an HBT.

The second problem is that breakage of base-emitter junction (which will hereinafter be called “B-E junction”) occurs in an HBT having a structure as illustrated in FIG. 25 and investigated by the present inventors.

FIG. 25 is a fragmentary schematic cross-sectional view of an HBT investigated by the present inventors and having a structure containing a ballast resistor layer and a semiconductor layer below the ballast resistor layer. It has a layer structure obtained by successively stacking, over a substrate 101 made of a semi-insulating GaAs layer, a sub-collector layer 102 made of an n type GaAs layer, a collector layer 103 made of an n type GaAs layer, a base layer 104 made of a p type GaAs layer, an emitter layer 105 made of an n type InGaP layer, a semiconductor layer 6 made of an n type GaAs layer, a ballast resistor layer 107 made of an n type AlGaAs layer, a contact layer 108 made of an n type GaAs layer and a contact layer 109 made of an n type InGaAs layer one after another. In FIG. 25, designated by 111, 112, and 113 are collector electrode, base electrode and emitter electrode, respectively.

When, for example, an excessive voltage generated by static electricity was applied to the HBT as illustrated in FIG. 25, breakdown (which will hereinafter be called electrostatic breakdown) of B-E junction sometimes occurred. Such electrostatic breakdown is presumed to occur because excessive electrons enter into the base side from the emitter electrode side.

In order to prevent electrostatic breakage of a B-E junction, it is effective to disturb excessive electrons from entering into the base side from the emitter electrode side.

The present inventors have found that compared with the HBT having a ballast-resistor-layer free structure as illustrated in FIG. 24, the HBT having a structure containing a ballast resistor layer and a semiconductor layer therebelow as illustrated in FIG. 25 tends to cause electrostatic breakdown.

As a result, the present inventors observed main portions of the HBTs having structures as illustrated in FIGS. 24 and 25, respectively. FIGS. 26 and 27 are fragmentary schematic cross-sectional views of the HBTs as illustrated in FIGS. 24 and 25, respectively. Designated by Reference numeral 106M in FIGS. 26 and 27 is an emitter mesa layer made of semiconductor layers formed between an emitter layer 105 and an emitter electrode 113. In this application, the term “emitter mesa layer” means semiconductor layers formed over the emitter layer up to the emitter electrode and it has almost a similar shape to that of the emitter electrode. The emitter layer and emitter mesa layer are sometimes embraced by the term “emitter layer”, but in this application, the term “emitter layer” means a semiconductor layer which forms a pn junction, while being brought into physical contact with the base layer, and has a function of injecting electrons toward the base in the case where it is, for example, an npn bipolar transistor. Thus, the emitter layer is distinguished from the emitter mesa layer. Accordingly, in FIG. 26, the emitter mesa layer 106M is composed of a semiconductor layer 106 made of an n type GaAs layer, a contact layer 108 made of an n type GaAs layer and a contact layer 109 made of an n type InGaAs layer, while in FIG. 27, the emitter mesa layer 106M is composed of a semiconductor layer 6 made of an n type GaAs layer, a ballast resistor layer 107 made of an n type AlGaAs layer, a contact layer 108 made of an n type GaAs layer and a contact layer 109 made of an n type InGaAs layer.

As is apparent from comparison between FIGS. 26 and 27, the emitter mesa layer 106M of the HBT as illustrated in FIG. 27 has a constricted cross-section, while that of the HBT as illustrated in FIG. 26 has a forward tapered cross-section. At this constriction, electric field concentration occurs so that the HBT having a structure containing a ballast resistor layer 107 and a semiconductor layer 106 therebelow as illustrated in FIG. 25 tends to cause electrostatic breakage compared with the HBT having a ballast-resistor-layer-free structure as illustrated in FIG. 24.

The reason why the emitter mesa layer 106M of the HBT containing a ballast resistor layer 107 made of an AlGaAs layer and an underlying semiconductor layer 106 made of a GaAs layer has a constricted cross-section is presumed to be as follows. The emitter mesa layer 106M is formed by wet etching with the emitter electrode 113 as a mask. When, for example, a 1:2:40 mixture of phosphoric acid, hydrogen peroxide and water is used as an etchant for the wet etching, constriction occurs because an etching rate of AlGaAs constituting the emitter mesa layer 106M is greater than that of GaAs. The ballast resistor layer made of, for example, an AlGaAs layer is however indispensable as described above in order to stabilize the heat-induced unstable operation.

Accordingly, prevention of electric field concentration at the above-described constricted portion is presumed to be effective for preventing electrostatic breakdown of HBT, thereby improving its reliability.

An object of the present invention is to provide a semiconductor device equipped with an HBT which can satisfy both thermal stability and reliability, and has improved electrostatic breakdown voltage; and a manufacturing technology of such a device.

Another object of the present invention is to provide an electronic device having a power amplifier equipped with an HBT which can satisfy both thermal stability and reliability, and has improved electrostatic breakdown voltage.

The above-described and other objects and novel features of the present invention will be apparent by the description herein and accompanying drawings.

The outline of the inventions typical of the inventions disclosed by the present application will next be described briefly.

The semiconductor device according to the present invention is a semiconductor device having a bipolar transistor made of a compound semiconductor, wherein the bipolar transistor has a substrate, a collector layer formed over the main surface of the substrate, a base layer formed over the collector layer, an emitter layer made of an InGaP layer formed over the base layer, a collector electrode electrically connected to the collector layer, a base electrode electrically connected to the base layer, an emitter mesa layer formed over the emitter layer and electrically connected to the emitter layer, and an emitter electrode electrically connected to the emitter mesa layer; the emitter mesa layer has a first semiconductor layer, a second semiconductor layer over the first semiconductor layer, and a ballast resistor layer formed over the second semiconductor layer and is composed of a semiconductor layer having a greater specific resistance than that of the second semiconductor layer; and the second semiconductor layer has a carrier concentration at least equal to that of the first semiconductor layer.

A manufacturing method of a semiconductor device according to the present invention is that of a semiconductor device having a bipolar transistor made of a compound semiconductor, wherein the bipolar transistor has a substrate, a collector layer formed over the main surface of the substrate, a base layer formed over the collector layer, an emitter layer made of an InGaP layer formed over the base layer, a collector electrode electrically connected to the collector layer, a base electrode electrically connected to the base layer, an emitter mesa layer formed over the emitter layer and electrically connected to the emitter layer, and an emitter electrode electrically connected to the emitter mesa layer; and the side surface portions of the emitter mesa layer is wet etched into a forward tapered shape or a constricted shape with the emitter electrode as a mask.

An electronic device according to the present invention is that having a power amplifier, wherein the power amplifier is composed of one or plural bipolar transistors each made of a compound semiconductor; the bipolar transistor has a substrate, a collector layer formed over the main surface of the substrate, a base layer formed over the collector layer, an emitter layer made of an InGaP layer formed over the base layer, a collector electrode electrically connected to the collector layer, a base electrode electrically connected to the base layer, an emitter mesa layer formed over the emitter layer and electrically connected to the emitter layer, and an emitter electrode electrically connected to the emitter mesa layer; the emitter mesa layer has a first semiconductor layer, a second semiconductor layer over the first semiconductor layer and a ballast resistor layer formed over the second semiconductor layer and composed of a semiconductor layer having a greater specific resistance than that of the second semiconductor layer; and the second semiconductor layer has a carrier concentration at least equal to that of the first semiconductor layer.

Advantages available by the inventions typical of the inventions disclosed by the present application will next be described briefly.

A semiconductor device equipped with an HBT which can satisfy both thermal stability and reliability and has improved electrostatic breakdown voltage can be provided.

An electronic device having a semiconductor device equipped with HBP which can satisfy both thermal stability and reliability and has improved electrostatic breakdown voltage can be provided.

### BRIEF DESCRIPTION OF DRAWINGS

FIG. 1 is a schematic plan view of a semiconductor device according to Embodiment 1 of the present invention;

FIG. 2 is a schematic cross-sectional view of the semiconductor device taken along a line A-A′ of FIG. 1;

FIG. 3 is a fragmentary schematic cross-sectional view of the semiconductor device according to Embodiment 1;

FIG. 4 is a schematic cross-sectional view of a semiconductor device investigated by the present inventors;

FIG. 5 is a schematic cross-sectional view of the semiconductor device according to Embodiment 1 during its manufacturing step;

FIG. 6 is a schematic cross-sectional view of the semiconductor device during a manufacturing step following that of FIG. 5;

FIG. 7 is a schematic cross-sectional view of the semiconductor device during a manufacturing step following that of FIG. 6;

FIG. 8 is a schematic cross-sectional view of the semiconductor device during a manufacturing step following that of FIG. 7;

FIG. 9 is a schematic cross-sectional view of the semiconductor device during a manufacturing step following that of FIG. 8;

FIG. 10 is a schematic cross-sectional view of the semiconductor device during a manufacturing step following that of FIG. 9;

FIG. 11 is a schematic cross-sectional view of the semiconductor device during a manufacturing step following that of FIG. 10;

FIG. 12 is a schematic cross-sectional view of the semiconductor device during a manufacturing step following that of FIG. 11;

FIG. 13 is a fragmentary schematic cross-sectional view of a semiconductor device investigated by the present inventors;

FIG. 14 is a fragmentary schematic cross-sectional view of a semiconductor device according to one example of Embodiment 3 of the present invention;

FIG. 15 is a schematic plan view of the semiconductor device according to Embodiment 3 during its manufacturing step;

FIG. 16 is a fragmentary schematic cross-sectional view of a semiconductor device investigated by the present inventors;

FIG. 17 is a fragmentary schematic cross-sectional view of the semiconductor device according to another example of Embodiment 3 of the present invention;

FIG. 18 is a fragmentary schematic cross-sectional view of a semiconductor device investigated by the present inventors;

FIG. 19 is a fragmentary schematic cross-sectional view of a semiconductor device according to Embodiment 4 of the present invention;

FIG. 20 is a block diagram of a power amplifier according to Embodiment 5 of the present invention;

FIG. 21 is a schematic cross-sectional view of an electronic device equipped with the power amplifier of FIG. 20;

FIG. 22 is a schematic cross-sectional view of an electronic device equipped with the power amplifier of FIG. 21;

FIG. 23 is a schematic cross-sectional view of a semiconductor device investigated by the present inventors;

FIG. 24 is a schematic cross-sectional view of another semiconductor device investigated by the present inventors;

FIG. 25 is a schematic cross-sectional view of a further semiconductor device investigated by the present inventors;

FIG. 26 is a fragmentary schematic cross-sectional view of the another semiconductor device investigated by the present inventors; and

FIG. 27 is a fragmentary schematic cross-sectional view of the further semiconductor device studied by the present inventors.

### DETAILED DESCRIPTION OF THE PREFERRED EMBODIMENTS

The embodiments of the present invention will next be described in detail based on accompanying drawings. In all the drawings for describing the embodiments, like members of a function will be identified by like reference numerals and overlapping descriptions will be omitted.

### Embodiment 1

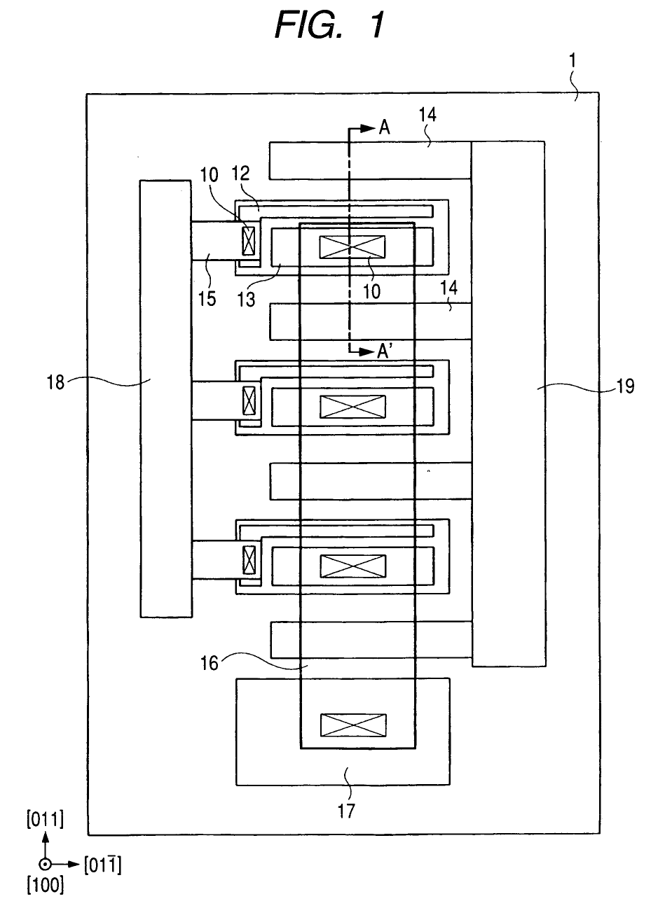

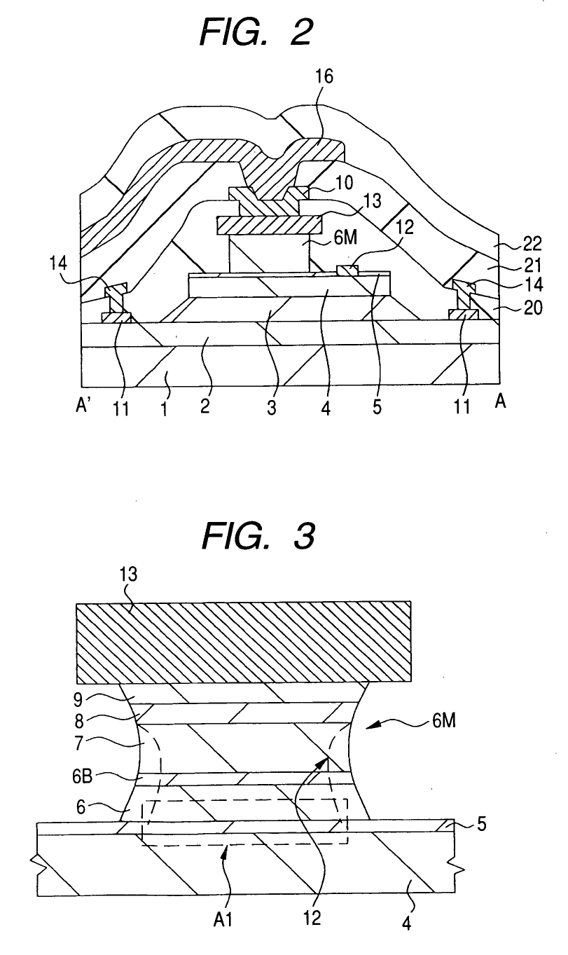

As one example of the semiconductor device according to the embodiment of the present invention, a semiconductor device equipped with a multifinger HBT for high power composed of a plurality of HBTs will next be described based on FIGS. 1 to 3. FIG. 1 is a schematic plan view of the semiconductor device, in which an emitter interconnect 16 is illustrated in perspective. FIG. 2 is a schematic cross-sectional view of the semiconductor device taken along a line A-A′ of FIG. 1. FIG. 3 is a fragmentary schematic cross-sectional view of the semiconductor device of FIG. 1. In this Embodiment, the semiconductor device is equipped with a plurality of HBTs, but it may be a semiconductor device equipped with one HBT. Incidentally, one HBT (which will hereinafter be called “basic HBT”) has an emitter area of 108 μm².

A sub-collector layer (Si concentration: 5×10¹⁸ cm⁻³, film thickness: 0.6 μm) 2 made of, for example, an n type GaAs layer is formed over a substrate 1 made of a semi-insulating GaAs compound semiconductor. Over the sub-collector layer 2, a collector layer (Si concentration: 1×10¹⁶ cm⁻³, film thickness: 1.0 μm) 3 made of, for example, an n type GaAs layer, a base layer (C concentration: 4×10¹⁹ cm⁻³, film thickness: 150 nm) 4 made of, for example, a p type GaAs layer, and an emitter layer (InP molar ratio: 0.5, Si concentration: 3×10¹⁷ cm⁻³, film thickness: 30 μm) 5 made of, for example, an n type IgGaP layer are formed. A base electrode 12 is disposed via this emitter layer 5.

Over the emitter layer 5, an emitter mesa layer 6M electrically connected to the emitter layer 5 is formed. This emitter mesa layer 6M is composed of a semiconductor layer (Si concentration: 3×10¹⁷ cm⁻³, film thickness: 90 nm) 6 made of, for example, an n type GaAs layer, a high-concentration semiconductor layer (Si concentration: 3×10¹⁸ cm⁻³, film thickness: 30 nm) 6B made of, for example, an n⁺ type GaAs layer, a ballast resistor layer (AlAs molar ratio: 0.33, Si concentration: 1×10¹⁷ cm⁻³, film thickness: 120 nm) 7 made of, for example, an n type AlGaAs layer, a contact layer (Si concentration: 5×10¹⁸ cm⁻³, film thickness: 50 nm) 8 made of, for example, an n type GaAs layer, and a contact layer (InAs molar ratio: 0.5, Si concentration: 1×10¹⁹ cm⁻³, film thickness: 50 nm) 9 made of, for example, an n type IgGaAs layer.

The ballast resistor layer 7 is, for example in the structure of a ballast resistor layer 7 made of an n type AlGaAs layer/(high-concentration semiconductor layer 6B made of an n⁺ type GaAs layer/) a semiconductor layer 6 made of an n type GaAs layer/an emitter layer 5 made of an n type InGaP layer, a semiconductor layer having a higher specific resistance than that of the (high concentration semiconductor layer 6B made of n⁺ type GaAs layer/) semiconductor layer 6 made of an n type GaAs layer.

Over the emitter mesa layer 6M, an emitter electrode 13 electrically connected to the emitter mesa layer 6M is disposed. Over the sub-collector layer 2, collector electrodes 11 are formed opposite to the both end portions of the collector layer 3. As illustrated in FIG. 1, the semiconductor device has a plane constitution in which the collector electrode 11 encompasses the emitter electrode 13, in other words, a collector region encompasses an emitter region.

Here, the emitter mesa layer 6M includes semiconductor layers up to the emitter electrode 13 formed over the emitter layer 5 and these semiconductor layers are processed into a substantially similar shape to that of the emitter electrode 13.

Specific examples of the collector electrode 11, base electrode 12 and emitter electrode 13 are a collector electrode 11 composed of a film stack of AuGe (film thickness: 60 nm)/Ni (film thickness: 10 nm)/Au (film thickness: 200 nm), a base electrode 12 composed of a film stack of Ti (film thickness: 50 nm)/Pt (film thickness: 50 nm)/Au (film thickness: 200 nm), and an emitter electrode 13 composed of WSi (Si molar ratio: 0.3, film thickness: 0.3 μm). In FIG. 1, reference numeral 10 designates a contact for electrically connecting an electrode and an interconnect, reference numerals 14, 15 and 16 designate a collector interconnect, a base interconnect and an emitter interconnect, respectively, and reference numerals 17, 18 and 19 are metal pads for electrical connection to the outside of HBT. In FIG. 2, reference numerals 20, 21 and 22 are interlayer insulating films made of, for example, silicon oxide.

The ballast resistor layer 7 made of, for example, an AlGaAs layer is required to work as a resistor and it must have a thickness of 10 nm or greater in order not to exhibit a quantum tunnel effect. The thickness of the ballast resistor layer 7 made of an AlGa As layer is determined so as to prevent exhibition of a quantum tunnel effect and in addition, depending on the request for its properties as a resistor. The ballast layer is able to have a thickness of even 200 nm. The semiconductor layer 6 made of an n type GaAs layer and the high concentration semiconductor layer 6B made of an n⁺ type GaAs layer serve as a so-called semiconductor layer between the emitter layer 5 made of an n type IgGaP layer and the ballast resistor layer 7 made of an n type AlGaAs layer. In this example, the AlAs molar ratio of the ballast resistor layer made of an n type AlGaAs layer is 0.33, but it may be 0 or greater.

A power distribution test of 20 basic HBTs as described in this embodiment was carried out under the following conditions: collector current density: 40 kA/cm² and junction temperature of 210° C. As a result, it was confirmed that they have good reliability. The reason of it will next be considered.

Supposing that the emitter layer 5 made of an n type InGaP layer, the semiconductor layer 6 made of an n type GaAs layer and the high concentration semiconductor layer 6B made of an n⁺ type GaAs layer are approximated to an n type GaAs, when the carrier concentration of the emitter layer 5, semiconductor layer 6 and high concentration semiconductor layer 6B is, for example, 3×10¹⁷ cm⁻³, a depletion layer of about 80 nm will extend from the junction surface toward the emitter side of a B-E junction (a reference numeral A1 in FIG. 3 designates a depleted region of the B-E junction). The surface (side surface) of the emitter mesa layer 6M formed over the emitter layer 5 is, on the other hand, depleted by a surface potential (a reference numeral A2 in FIG. 3 designates a depleted region of surface) and recombination occurs at a surface trap level of this surface depleted region A2, whereby a recombination current flows. The surface region of the ballast resistor layer 7 must be separated from the B-E junction surface.

As a result, when the carrier concentration of the emitter layer 5, semiconductor layer 6 and high concentration semiconductor layer 6B is approximately 3×10¹⁷ cm⁻³, it is preferred to increase the distance between the B-E junction surface and the ballast resistor layer 7 to at least about two to three times as much as the elongation, that is, 80 nm of the depletion layer. As a rough guide, an areal concentration (sheet carrier concentration) Ns of the semiconductor layer 6 or high concentration semiconductor layer 6B from the B-E junction surface to the ballast resistor layer 7 is set to 3×10¹⁷ cm⁻³×80 nm×3=about 7×10¹² cm⁻² or greater. The following relationship will provide a guide for determination of the distance:
Ns=TH×NH+TL×NL+TI×NI>7×10¹¹ cm⁻²
wherein TH and NH represent the thickness and carrier concentration of the high concentration semiconductor layer 6B, respectively, TL and NL represent thickness and carrier concentration of the semiconductor layer 6, respectively, and TI and NI represent the thickness and carrier concentration of the emitter layer 5, respectively.

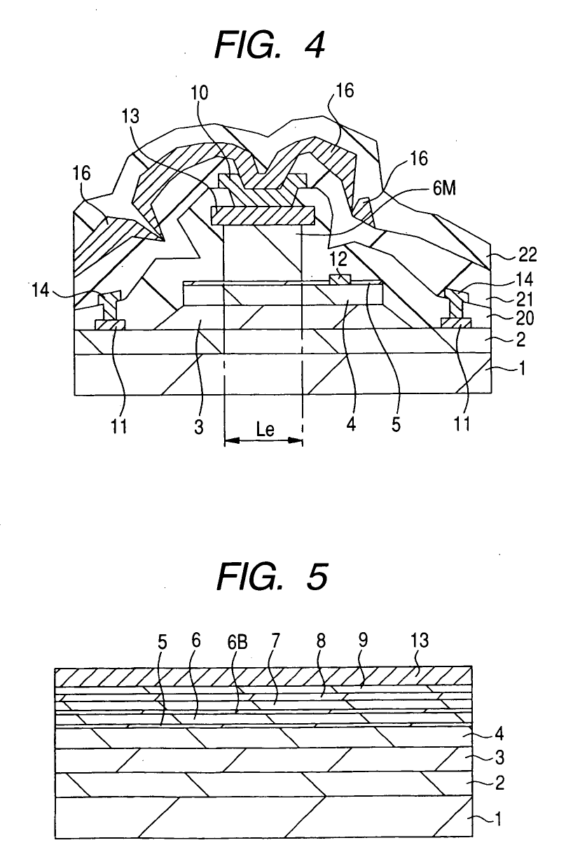

The thickness TL of the semiconductor layer 6 and the thickness TH of the high concentration semiconductor layer 6B are preferably decreased because the emitter mesa layer 6M must be thinned. Thick emitter mesa layer 6M tends to disturb smooth formation of an interconnect on the emitter. FIG. 4 is a schematic cross-sectional view of a semiconductor device equipped with an HBT investigated by the present inventors and it has a thick emitter mesa layer 6M.

When the interconnect is formed by the lift off method as illustrated in FIG. 4, disconnection or thinning of an interconnect 16 of the emitter occurs at the stepped portion of the emitter mesa layer 6M, which becomes a problem. When an Au interconnect is processed by sputter etching, an etching residue remains by the processing at the stepped portion of the emitter layer 5 and a problem such as short-circuit tends to occur. The collector layer 3 can be processed into a tapered shape so that a disconnection problem of an upper interconnect can be avoided. This method cannot be applied to the emitter mesa layer 6M, because processing of it into a tapered shape undesirably increases the length Le of the junction surface between the emitter mesa layer 6M and emitter layer 5, making it difficult to control the processing. In other words, the size of B-E junction is determined, depending on the length of this junction surface Le and an increase in the length Le leads to a difference in the principal properties of the HBT. Although there is a possibility of forming a flat surface by isolation by the ion implantation, this method cannot be employed here because defects enter into the emitter mesa layer 6M and become a cause for deterioration in the reliability of the HBT.

The thickness TL of the semiconductor layer 6 and the thickness TH of the high concentration semiconductor layer 6B are preferably reduced and those roughly satisfying the following relation are preferred:
TH+TL<150 nm (2)

When the thickness TL of the semiconductor layer 6 is too thin, the breakdown voltage Bvcbo of the B-E junction decreases so that the thickness TL of the semiconductor layer 6 preferably satisfies the following equation:
TL≧50 nm (3)
When the thickness TL of the semiconductor layer 6 is about 50 nm, the breakdown voltage Bvcbo is about 7V.

In this Embodiment, any of the area concentration Ns=1.3×10¹¹ cm⁻² and the equations (1), (2) and (3) can be satisfied by adjusting the thickness TH and the carrier concentration NH of the high concentration semiconductor layer 6B to about 30 nm and 3×10¹⁸ cm⁻³, respectively, the thickness TL and the carrier concentration NL of the semiconductor layer 6 to about 90 nm and 3×10¹⁷ cm⁻³, respectively, and thickness TI and carrier concentration NI of the emitter layer 5 to 30 nm and 3×10¹⁷ cm⁻³, respectively. It is therefore possible to avoid occurrence of a recombination current in the ballast resistor layer 7, thereby improving the power distribution reliability, by inserting the high concentration semiconductor layer 6B which is a high concentration semiconductor layer, below the ballast resistor layer 7 and completely preventing the depletion layer extending from the B-E junction from reaching the ballast resistor layer 7. In this embodiment, the semiconductor layer 6 and high concentration semiconductor layer 6B are inserted between the emitter layer 5 and the ballast resistor layer 7. Alternatively, it is possible to avoid the insertion of the semiconductor layer 6 and to insert only the high concentration semiconductor layer (Si concentration: 3×10¹⁸ cm⁻³, film thickness: 100 nm) 6B made of an n⁺ type GaAs layer.

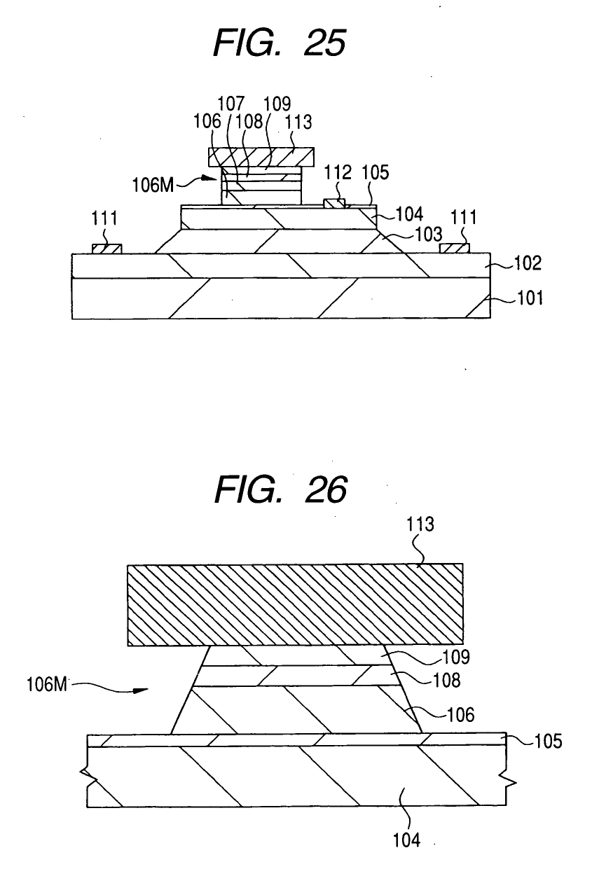

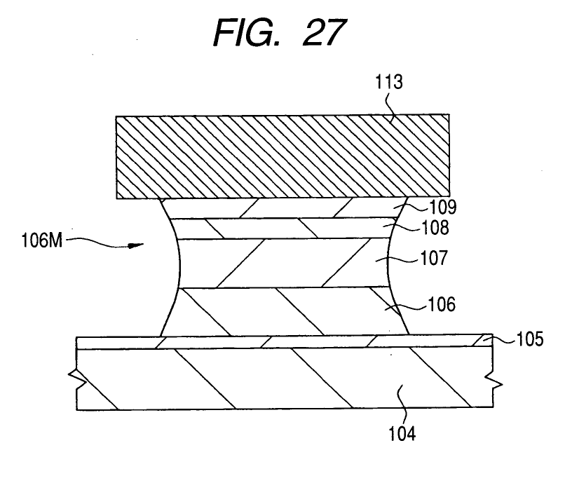

The forward electrostatic breakdown voltage of the HBT in this embodiment increases to about 30V, about 10V higher than that of an HBT having a structure free of a high concentration semiconductor layer as illustrated in FIG. 25. Electrostatic breakdown occurs, for example, when excessive electrons enter into the base from the side of the emitter electrode and break down the B-E junction. It is presumed to be able to relax the breakdown of the B-E junction by inserting the high concentration semiconductor layer 6, which is a high concentration semiconductor layer, into the emitter mesa layer 6M to increase the B-E junction capacitance and allowing the high concentration semiconductor layer 6B, which is a high concentration semiconductor layer, to absorb a portion of excessive charges.

It can be confirmed by the above-described consideration that the HBT according to this Embodiment can satisfy both the thermal stability and reliability and is a good HBT from the standpoint of electrostatic breakdown.

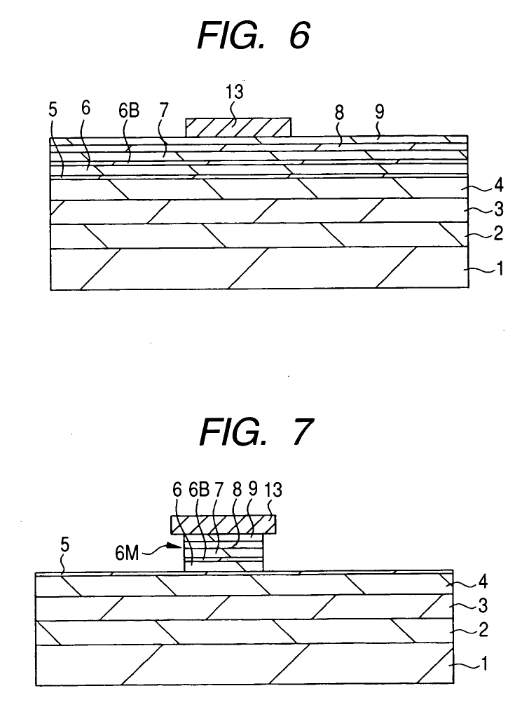

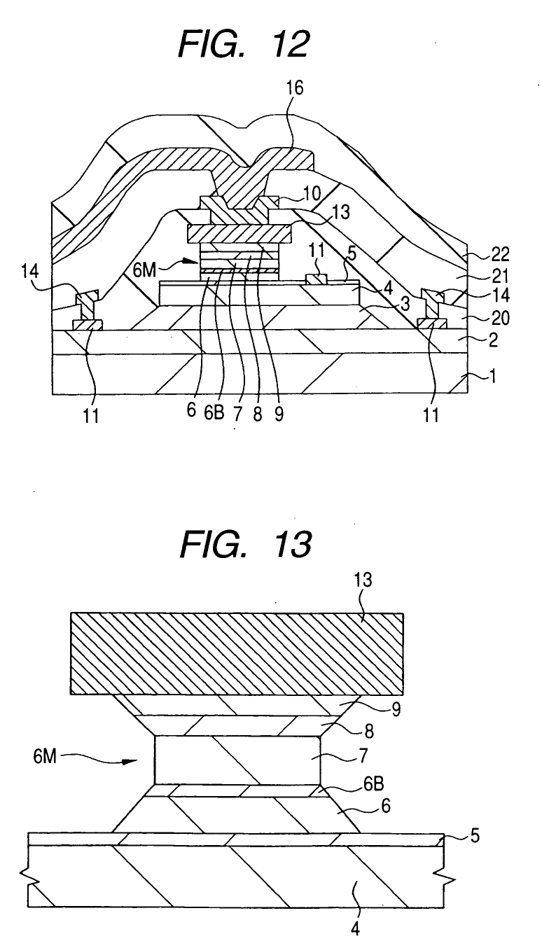

A manufacturing technology of the semiconductor device equipped with a multifinger HBT for high power according to this Embodiment will next be described based on FIGS. 5 to 13. FIGS. 5 to 12 are schematic cross-sectional views of the semiconductor device of this Embodiment during its manufacturing steps. FIG. 13 is a schematic cross-sectional view illustrating the main portion of the semiconductor device investigated by the present inventors. FIG. 12 is a schematic cross-sectional view of the semiconductor device taken along a lone A-A′ of FIG. 1.

As illustrated in FIG. 5, a sub-collector layer (Si concentration: 5×10¹⁸ cm⁻³, film thickness: 0.6 μm) 2 made of an n type GaAs layer, a collector layer (Si concentration 1×10¹⁶ cm⁻³, film thickness: 1.0 μm) 3 made of an n type GaAs layer, a base layer (C concentration: 4×10¹⁹ cm⁻³, film thickness 150 nm) 4 made of a p type GaAs layer, an emitter layer (InP molar ratio: 0.5, Si concentration: 3×10¹⁷ cm⁻³, film thickness 30 nm) 5 made of an n type InGaP layer are made to grow over a substrate 1 made of a semi-insulating GaAs substrate by a metal organic vapor phase epitaxy method.

Then, a semiconductor layer (Si concentration: 3×10¹⁷ cm⁻³, film thickness: 90 nm) 6 made of an n type GaAs layer, a high concentration semiconductor layer (Si concentration 3×10¹⁸ cm⁻³, film thickness: 30 nm) 6B made of an n⁺ type GaAs layer, a ballast resistor layer (AlAs molar ratio: 0.33, Si concentration: 1×10¹⁷ cm⁻³, film thickness 120 nm) 7 made of an n type AlGaAs layer, a contact layer (Si concentration: 1×10¹⁹ cm⁻³, film thickness: 50 nm) 8 made of an n type GaAs layer and a contact layer (InAs molar ratio: 0.5, Si concentration: 1×10¹⁹ cm⁻³, film thickness: 50 nm) 9 made of an n type InGaAs layer are made to grow over the emitter layer 5 by a metal organic vapor phase epitaxy method. Thereafter, a WSi (Si molar ratio: 0.3, film thickness 0.3 μm) layer is deposited on the entire surface of a wafer by using a high frequency sputtering method.

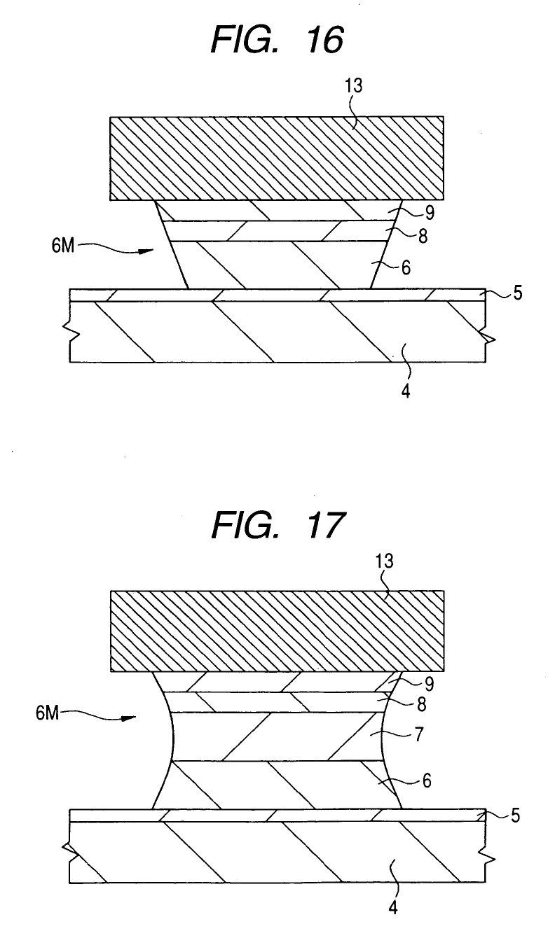

As illustrated in FIG. 16, the WSi layer is then processed into an emitter electrode 13 by photolithography and dry etching using CF₄. Here, the emitter electrode 13 is formed, as illustrated in FIG. 1, so that it has a rectangular plane shape and has a [01-1] direction of the wafer as its longitudinal direction.

As illustrated in FIG. 7, the contact layer 9 made of an n type InGaAs layer, contact layer 8 made of an n type GaAs layer, ballast resistor layer 7 made of an n type AlGaAs layer, high concentration semiconductor layer 6B made of an n⁺ type GaAs layer and semiconductor layer 6 made of an n type GaAs layer are processed into a desired shape to form an emitter region. They are processed, for example, in the following manner. With the emitter electrode 13 as a mask, an unnecessary region is removed from the contact layer 9 made of an n type InGaAs layer, contact layer 8 made of an n type GaAs layer, ballast resistor layer 7 made of an n type AlGaAs layer, high concentration semiconductor layer 6B made of an n⁺ type GaAs layer and semiconductor layer 6 made of an n type GaAs layer by wet etching using an etchant (composition example of the etchant:phosphoric acid:aqueous hydrogen peroxide:water=1:2:40). In short, an emitter mesa layer 6M is thus formed. The longitudinal direction of the emitter electrode 13 has a [01-1] direction of the wafer so that the emitter mesa layer 6M is formed so that it also has a [01-1] direction of the wafer as its longitudinal direction.

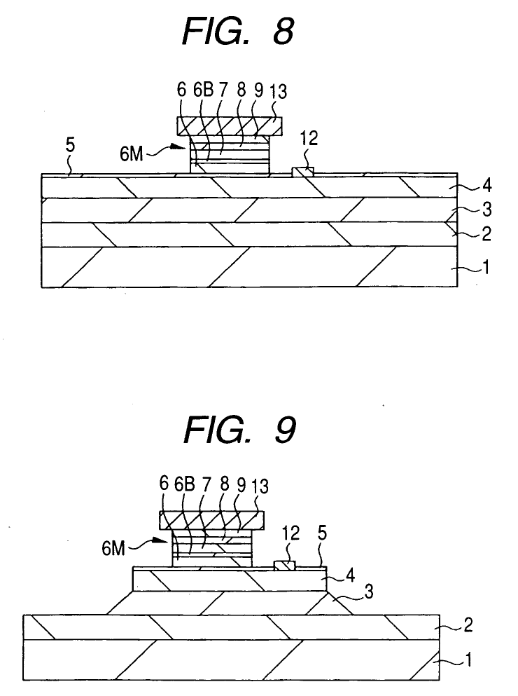

As illustrated in FIG. 8, a base electrode 12 composed of Ti (film thickness: 50 nm)/Pt (film thickness: 50 nm)/Au (film thickness: 200 nm) and penetrating through the emitter layer 5 is formed over the base layer 4 by an ordinarily employed lift-off method.

As illustrated in FIG. 9, desired regions are removed from the emitter layer 5 made of an n type InGaP layer, base layer 4 made of a p type GaAs layer and collector layer 3 made of an n type GaAs layer are removed by photolithography and wet etching to expose the sub-collector layer 2 made of an n type GaAs layer, whereby a base region is formed. The etchants used for etching are as follows. The etchant used for etching of the emitter layer 5 made of an n type InGaP layer is hydrochloric acid, while that used for etching of the base layer 4 made of a p type GaAs layer and collector layer 3 made of an n type GaAs layer has a composition, for example, phosphoric acid:aqueous hydrogen peroxide:water=1:2:40.

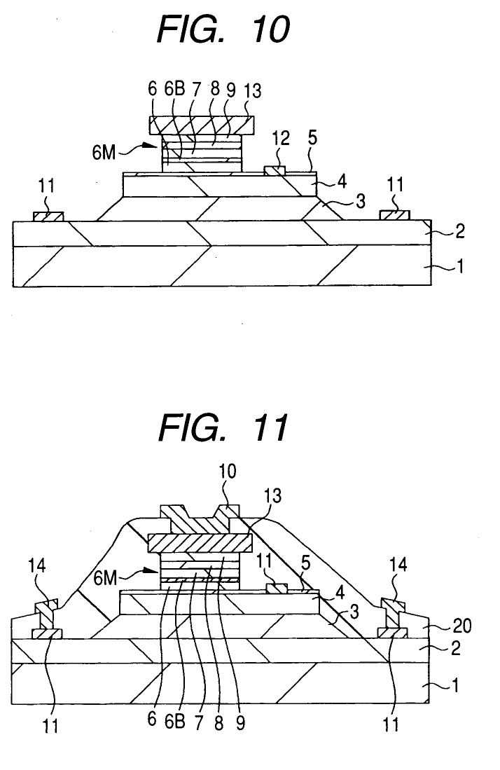

As illustrated in FIG. 10, a collector electrode 11 is formed by an ordinarily employed lift-off method and alloyed at 350° C. for 30 minutes. The collector electrode 11 is composed of a film stack of AuGe (film thickness: 60 nm)/Ni (film thickness: 10 nm)/Au (film thickness: 200 nm).

As illustrated in FIG. 11, an interlayer insulating film 20 made of, for example, a silicon oxide film formed by CVD is then opened above the emitter electrode 13 and collector electrode 11 and a metal film is formed. This metal film over the emitter electrode 13 serves to form a contact 10, while the metal film over the collector electrode 11 serves to form a collector interconnect 14.

As illustrated in FIG. 12, an interlayer insulating film 21 made of, for example, a silicon oxide film formed by CVD is then opened on the contact hole 10 and a metal film is formed thereover. The metal film over this contact hole 10 forms an emitter interconnect 16. An interlayer insulating film 22 is then formed by CVD, whereby a semiconductor device equipped with a multifinger HBT for high power is completed.

In this Embodiment, the high concentration semiconductor layer 6B is inserted between the emitter layer 5 and the ballast resistor layer 7 in order to prevent the ballast resistor layer being depleted by the depletion layer extending from the B-E junction and to prevent excessive electrons from entering into the base side from the emitter electrode side. As a result, it is possible to obtain an HBT capable of satisfying both thermal stability and reliability and being excellent from the standpoint of electrostatic breakdown.

In this Embodiment, the HBT is formed so that the longitudinal direction of the emitter mesa layer 6M becomes a [01-1] direction of the wafer. In the next place, an HBT formed so that the longitudinal direction of the emitter mesa layer 6M becomes a direction other than the [01-1] direction of the wafer. FIG. 13 is a fragmentary schematic cross-sectional view of a semiconductor device investigated by the present inventors. In the HBT formed so that the longitudinal direction of the emitter mesa layer 6M becomes a [01-1] direction of the wafer, the emitter mesa layer 6M is relatively mildly constricted at the side surface portions thereof. When an HBT is formed so that the longitudinal direction of the emitter mesa layer 6M becomes a direction other than [01-1] direction of the wafer, for example, a [011] direction, on the other hand, the emitter mesa layer 6M is, at surface side portions thereof, more steeply constricted than that of FIG. 3 as illustrated in FIG. 13. Stress concentration and electric field concentration occur when the emitter mesa layer 6M has such a steep shape.

In the ballast resistor layer made of an AlGaAs layer, crystal defects therefore appear owing to stress concentration. Supposing that holes adversely injected into the side of the emitter layer 5 made of an n type InGaP layer from the base layer 4 made of a p type GaAs layer reach the ballast resistor layer made of an AlGaAs layer by the diffusion, the holes thus diffused are recombined with electrons via a DX center and energy released at this time proliferates crystal defects, which will lead to a deterioration in the device. In addition, in the ballast resistor layer made of an AlGaAs layer, field effect concentration occurs, which is presumed to easily cause electrostatic breakage of an HBT.

By forming the emitter mesa layer 6M so that the longitudinal direction of the emitter mesa layer 6M becomes a [01-1] direction of a wafer as described above, it is possible to form the side surface portions of the emitter mesa layer 6M into a relatively mildly constricted shape, thereby relaxing stress concentration and field effect concentration on the side surface portions of the emitter mesa layer 6M. As a result, an HBT capable of satisfying both the thermal stability and reliability and has improved electrostatic breakdown voltage can be obtained.

### Embodiment 2

In Embodiment 1, the ballast resistor layer is made of AlGaAs. In this Embodiment, a semiconductor device equipped with an HBT using a ballast resist layer made of AlGaInP or GaInAsP will be described as one example. The content of Embodiment 2 overlapped with that of Embodiment 1 is omitted from the description.

The semiconductor device according to this Embodiment is, as described using FIG. 2 in Embodiment 1, has an emitter layer 5 made of, for example, an n type InGaP layer, an emitter mesa layer 6M electrically connected to the emitter layer 5 and an emitter electrode 13 electrically connected to the emitter mesa layer 6M formed over a base layer 4 made of, for example, a p type GaAs layer.

As described above referring to FIG. 3 in Embodiment 1, this emitter mesa layer 6M has, over the emitter layer 5, a semiconductor layer 6 made of, for example, an n type GaAs layer, a high concentration semiconductor layer 6B made of, for example, an n⁺ type GaAs layer, a ballast resistor layer 7 made of, for example, an n type GaInAsP layer, a contact layer 8 made of, for example, an n type GaAs layer and a contact layer 9 made of, for example, an n type InGaAs layer.

This emitter mesa layer 6M is processed, as described referring to FIG. 7 in Embodiment 1, by removing unnecessary portions from the contact layer 9 made of an n type InGaAs layer, contact layer 8 made of an n type GaAs layer, ballast resistor layer 7 made of an n type AlGaInP or n type GaInAsP layer, high concentration semiconductor layer 6B made of an n⁺ type GaAs layer and semiconductor layer 6 made of an n type GaAs layer by wet etching using an etchant with the emitter electrode 13 as a mask. When the ballast resistor layer 7 is made of an n type AlGaInP layer, an etchant used therefor is a mixture of sulfuric acid, hydrogen peroxide and water, while the ballast resistor layer 7 is made of an n type GaInAsP layer, an etchant used therefor is a mixture of hydrochloric acid, nitric acid and water. As described referring to FIG. 3 in Embodiment 1, the emitter mesa layer 6M in this Embodiment has also a mildly constricted cross-section.

In the HBT according to Embodiment 1, AlGaAs is used for the ballast resistor layer 7. It is also possible to attain similar properties by the HBT using AlGaInP or GaInAsP for the ballast resistor layer 7 as in this Embodiment.

In this Embodiment, the high concentration semiconductor layer 6B is inserted between the ballast resistor layer 7 and semiconductor layer 6, but the high concentration semiconductor layer 6B is not always necessary. As shown in Embodiment 1, however, by inserting the high concentration semiconductor layer 6B, which is a high concentration semiconductor layer, below the ballast resistor layer 7, thereby preventing the depletion layer extending from the B-E junction from completely reaching the ballast resistor layer 7, a recombination current can be eliminated from the ballast resistor layer 7. In this manner, the power distribution reliability can be improved. In addition, by inserting the high concentration semiconductor layer 6B which is a high concentration semiconductor layer into the emitter mesa layer 6M, the B-E junction capacitance increases, making it possible to allow the high concentration semiconductor layer 6B which is a high concentration semiconductor layer to absorb therein a portion of excessive charges and relax the breakdown of the B-E junction.

### Embodiment 3

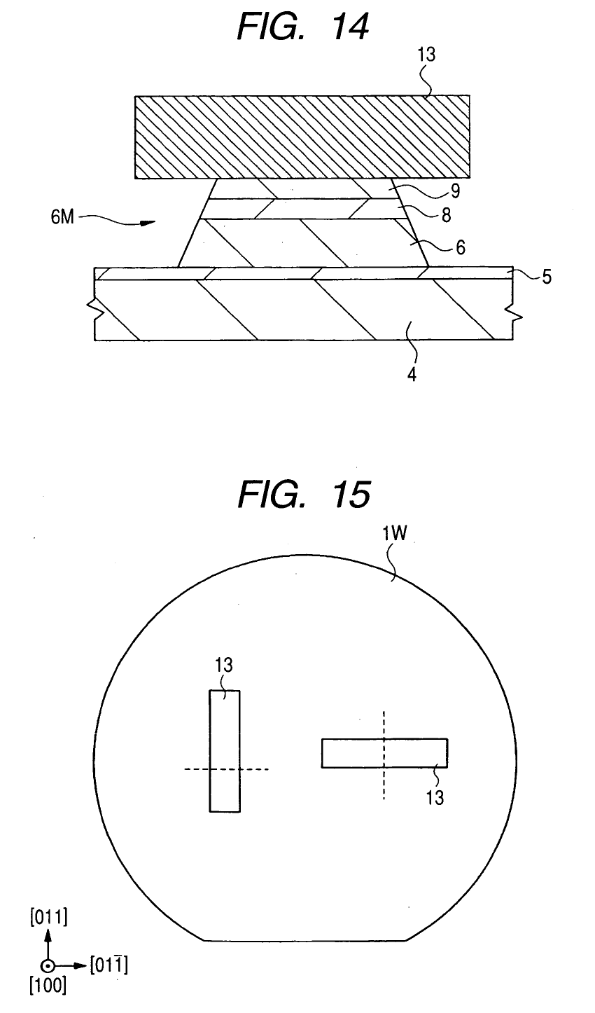

In Embodiment 1, the emitter mesa layer 6M has both the ballast resistor layer 7 and high concentration semiconductor layer 6B therebelow. In this Embodiment, on the other hand, a semiconductor device equipped with an HBT having an emitter mesa layer 6M containing neither a ballast resistor layer 7 nor a high concentration semiconductor layer 6B, or an emitter mesa layer 6M not containing only the high concentration semiconductor layer 6B will be described as one example, based on FIGS. 14 to 18. The content of Embodiment 3 overlapped with that of Embodiment 1 is omitted from the description.

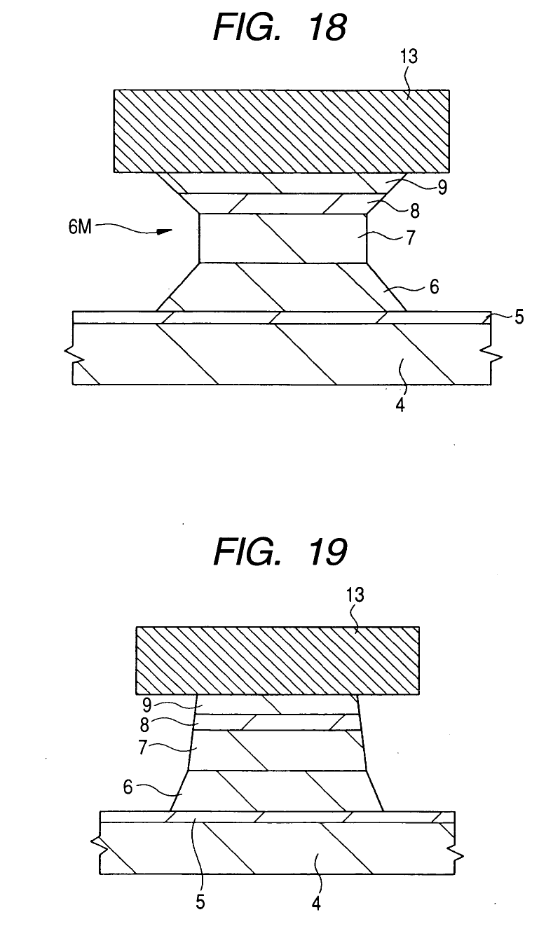

FIG. 14 is a fragmentary schematic cross-sectional view of the semiconductor device according to one example of this Embodiment. FIG. 15 is a schematic plan view of the semiconductor device according to the one embodiment during its manufacturing step. FIG. 16 is a fragmentary schematic cross-sectional view of the semiconductor device investigated by the present inventors. FIG. 17 is a fragmentary schematic cross-sectional view of a semiconductor device according to another example of this Embodiment. FIG. 18 is a fragmentary schematic cross-sectional view of the semiconductor device investigated by the present inventors.

The semiconductor device according to this Embodiment is, as described referring to FIG. 2 in Embodiment 1, has an emitter layer 5 made of, for example, an n type InGaP layer, an emitter mesa layer 6M electrically connected to the emitter layer 5 and an emitter electrode 13 electrically connected to the emitter mesa layer 6M formed over a base layer 4 made of, for example, a p type GaAs layer.

First, the emitter mesa layer 6M containing neither the ballast resistor layer 7 nor high concentration semiconductor layer 6B will be described. As illustrated in FIG. 14, this emitter mesa layer 6M has, over the emitter layer 5, a semiconductor layer (Si concentration: 3×10¹⁷ cm⁻³, film thickness: 90 nm) 6 made of, for example, an n type GaAs layer, a contact layer 8 made of, for example, an n type GaAs layer and a contact layer 9 made of, for example, an n type IgGaAs layer. The emitter mesa layer 6M according to this Embodiment has a forward tapered cross-section.

Such an emitter mesa layer 6M having a forward tapered shape is formed in the following manner. First, an emitter electrode 13 in the rectangular shape is formed as illustrated in FIG. 15 so that its longitudinal direction becomes a [01-1] direction of a wafer 1W. As described referring to FIG. 7 in Embodiment 1, with the emitter electrode 13 as a mask, unnecessary regions are removed from the contact layer 9 made of an n type IgGaAs layer, contact layer 8 made of an n type GaAs layer and semiconductor layer 6 made of an n type GaAs layer by wet etching using an etchant (a 1:2:4 mixture of phosphoric acid, hydrogen peroxide and water). The emitter electrode 13 has, as its longitudinal direction, a [01-1] direction of the wafer so that the emitter mesa layer 6M is also formed so that its longitudinal direction becomes a [01-1] direction of the wafer.

In this case, as illustrated in FIG. 14, the side surface portions of the emitter mesa layer 6M each has a forward tapered shape. As illustrated in FIG. 15, when an HBT is formed so that the longitudinal direction of the emitter electrode 13, that is, the longitudinal direction of the emitter mesa layer 6M has a direction other than the [01-1] direction of the wafer 1W, for example, a [011] direction, the side surface portions of the emitter mesa layer 6M have an inverse tapered shape.

In the next place, the emitter mesa layer 6M not containing only the high concentration semiconductor layer 6B will be described. When the ballast resistor layer 7 made of, for example, an n type AlGaAs layer is inserted between the contact layer 8 and semiconductor layer 6 of the emitter mesa layer 6M, the emitter mesa layer 6M formed so that the longitudinal direction of the emitter mesa layer 6M becomes a [01-1] direction of the wafer has, at the side surface portions of the emitter mesa layer 6M, a mildly constricted shape as illustrated in FIG. 17. When the ballast resistor layer 7 made of, for example, an n type AlGaAs layer is inserted between the contact layer 8 and semiconductor layer 6 of the emitter mesa layer 6M, the emitter mesa layer 6M formed so that the longitudinal direction of the emitter mesa layer 6M becomes a [011] direction of the wafer, has at the side surface portions of the emitter mesa layer 6M a more steeply constricted shape than that of FIG. 17 as illustrated in FIG. 18.

A power distribution test was conducted on the HBT (which will hereinafter be called “forward mesa HBT”) having an emitter mesa layer 6M formed so that the longitudinal direction of the emitter mesa layer 6M becomes a [01-1] direction of the wafer 1W and the HBT (which will hereinafter be called “inverse mesa HBT”) having an emitter mesa layer 6M formed so that the longitudinal direction of the emitter mesa layer 6M becomes a [011] direction of the wafer 1W. Incidentally, the emitter mesa layer 6M in the rectangular shape has a plane shape of approximately 4 μm×28 μm.

As a result, it has been understood that the inverse mesa HBT is not suited for practical use judging from occurrence of deterioration in h_{FE} for a period as short as 100 hours or less. The forward mesa HBT, on the other hand, endured the reliability test for 100 hours or more and produced good results.

Such results in the emitter mesa layer 6M having a steeply constricted shape are presumed to owe to crystal defects generated by the stress concentration, particularly, the stress concentration in the ballast resistor layer 7 made of an AlGaAs layer. Supposing that holes adversely injected from the base layer made of a p type GaAs layer into the side of the emitter layer 5 made of an n type InGaP layer reach the ballast resistor layer 7 made of an AlGaAs layer by diffusion, the holes thus diffused are recombined with electrons via an impurity level formed by lattice defects resulting from stress concentration and crystal defects are proliferated further by the energy released at this time, which leads to deterioration in the device. In other words, an accelerated increase in the recombination current increases a base current, which is presumed to accompanied by lowering (deterioration) in h_{FE}. By forming the emitter mesa layer 6M so that the longitudinal direction of the emitter mesa layer 6M becomes a [01-1] direction of the wafer, thereby forming the side portions of the emitter mesa layer 6M into a relatively mildly constricted shape as illustrated in FIG. 17 to relax stress concentration onto the side surface portions of the emitter mesa layer 6M, it is possible to prevent generation of crystal defects in the ballast resistor layer 7 which will otherwise occur by the stress concentration.

In the HBT having the ballast resistor layer 7 made of an AlGaAs layer, electrostatic breakdown tends to occur owing to the field effect concentration. By forming the emitter mesa layer 6M so that the longitudinal direction of the emitter mesa layer 6M becomes a [01-1] direction of the wafer, however, the side surface portions of the emitter mesa layer 6M can be formed into a relatively mildly constricted shape and field effect concentration onto the side surface portions of the emitter mesa layer 6M can be relaxed.

It can thus be confirmed that the HBT according to this Embodiment can satisfy both thermal stability and reliability and is a good HBT from the standpoint of electrostatic breakdown.

### Embodiment 4

In Embodiments 1 and 3, a mixture of phosphoric acid, hydrogen peroxide and water is used as an etchant for the formation of a ballast resistor layer composed mainly of an AlGaAs layer. In this Embodiment, on the other hand, a semiconductor device equipped with an HBT having an emitter mesa layer 6M formed using as an etchant a mixture of phosphoric acid, hydrogen peroxide, and ethylene glycol will be described in FIG. 19 as one example. The content of Embodiment 4 overlapped with that of Embodiment 1 is omitted from the description.

The semiconductor device according to this Embodiment has, as described referring to FIG. 2 in Embodiment 1, an emitter layer 5 made of, for example, an n type IgGaP layer, an emitter mesa layer 6M electrically connected to the emitter layer 5 and an emitter electrode 13 electrically connected to the emitter mesa layer 6M over a base layer 4 made of, for example, a p type GaAs layer. FIG. 19 is a fragmentary schematic cross-sectional view of the semiconductor device according to the one example of this Embodiment.

As illustrated in FIG. 19, this emitter mesa layer 6M has a semiconductor layer 6 made of, for example, an n type GaAs layer, a ballast resistor layer 7 made of, for example, an n type AlGaAs layer, a contact layer 8 made of, for example, an n type GaAs layer, and a contact layer 9 made of, for example, an n type InGaAs layer formed successively over the emitter layer 5.

The emitter mesa layer 6M is processed in the following manner. As described referring to FIG. 7 in Embodiment 1, with the emitter electrode 13 as a mask, an unnecessary region is removed from the contact layer 9 made of an n type InGaAs layer, contact layer 8 made of an n type GaAs layer, ballast resistor layer 7 made of an n type AlGaAs layer, and semiconductor layer 6 made of an n type GaAs layer by wet etching using an etchant. The etchant used here is a mixture of phosphoric acid, hydrogen peroxide and ethylene glycol. In this case, the emitter mesa layer 6M has, as illustrated in FIG. 19, side portions in the forward tapered shape.

A power distribution reliability test was conducted on an HBT having an emitter mesa layer 6M formed using, as an etchant, a mixture of phosphoric acid, hydrogen peroxide and ethylene glycol so that the longitudinal direction of the emitter mesa layer 6M becomes a [01-1] direction of the wafer. This HBT produced better results compared with the HBT shown in Embodiment 3 and having the emitter mesa layer 6M formed using, as an etchant, a mixture of phosphoric cid, hydrogen peroxide and water. The electrostatic breakdown strength of the HBT obtained in this Embodiment is also superior to that of the HBT of Embodiment 3.

The above-described results suggest that stress concentration and field effect concentration can be relaxed further by forming the emitter mesa layer 6M so that the longitudinal direction of the emitter mesa layer 6M becomes a [01-1] direction of the wafer and using a mixture of phosphoric acid, hydrogen peroxide and ethylene glycol as an etchant.

### Embodiment 5

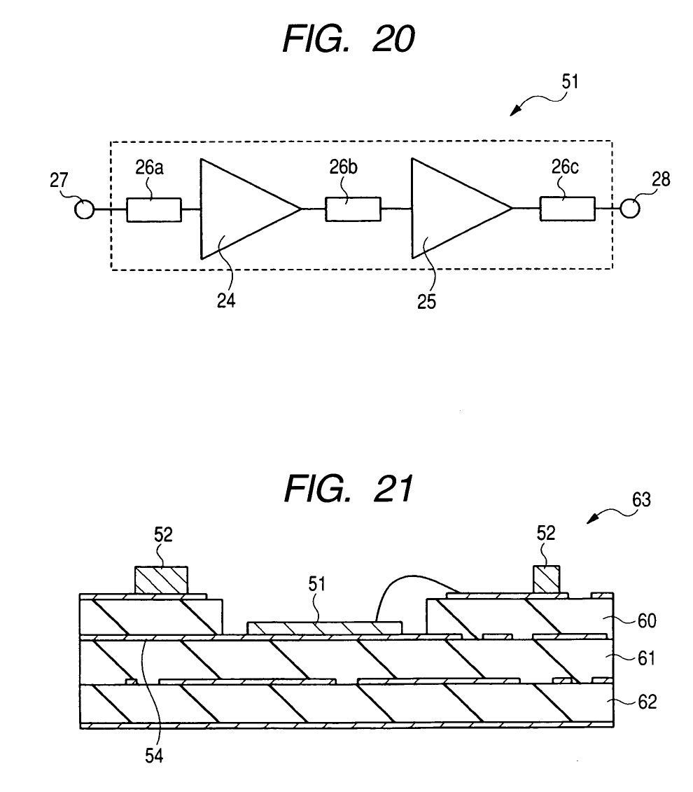

An electronic device having the semiconductor device as shown in any one of Embodiments 1 to 4 will next be described referring to FIGS. 20 to 22 as one example of an electronic device according to an embodiment of the present invention. The semiconductor device in this Embodiment is a power amplifier such as MMIC (Microwave Monolithic Integrated Circuit) and the electronic device is, for example, a power amplifier module.

FIG. 20 is a block diagram of a power amplifier 51. In this example, a power amplifier having two amplifier stages is shown. In this diagram, reference numerals 24 and 25 designate a first amplifier circuit and a second amplifier circuit, respectively. Designated at reference numerals 26a, 26b and 26c are input matching circuit, interstage matching circuit and output matching circuit, respectively. High frequency signals to be amplified are input from a high frequency input terminal 27 to the power amplifier and after amplification via the matching circuits 26a, 26b and 26c and amplifier circuits 24 and 25, are output from a high frequency output terminal 28. The above-described first amplifier circuit 24 and second amplifier circuit 25 are composed of multifinger HBTs in which 10 basic HBTs and 60 basic HBTs, each having an emitter area of 108 μm², are arranged in parallel, respectively. In other words, the bases, emitters and collectors of basic HBTs are connected each other and form a parallel connection.

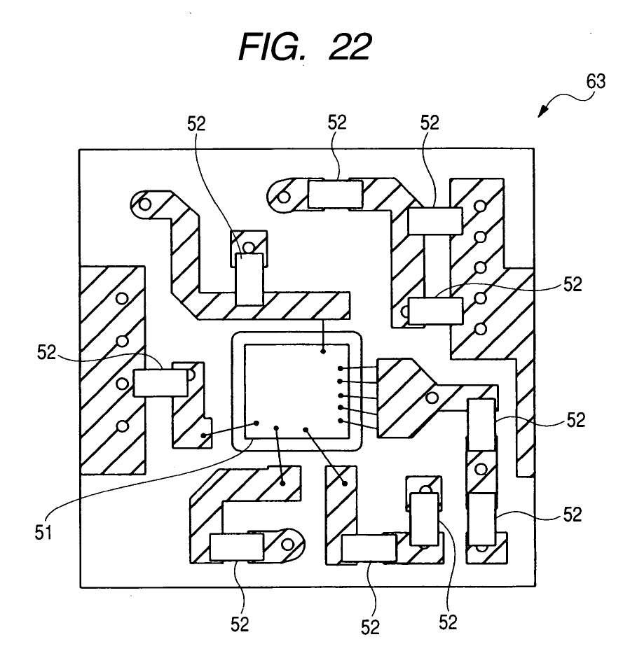

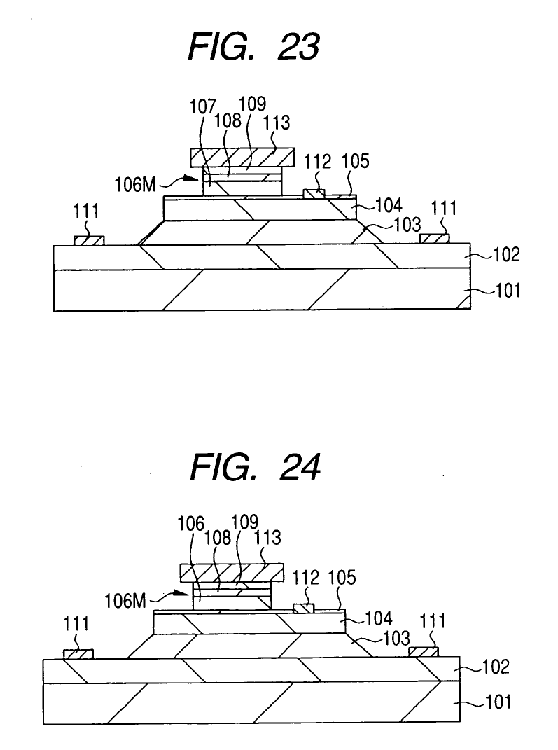

FIGS. 21 and 22 are schematic cross-sectional view and a schematic plan view illustrating the mounting state of the power amplifier module 63, respectively. The power amplifier module 63 has a frequency range of about 500 MHz or greater and is, for example, a power amplifier module for transmission which accepts a GSM (Global System for Mobile Communication) system having a frequency range of from about 800 MHz to 900 MHz, a DCS (Digital Cellular System) having a frequency range of from about 1.8 GHz to 1.9 GHz or both of these two systems. The power amplifier 51 and a passive element 52 are mounted on a mounting board 60. Designated at reference numeral 54 is a conductor layer and it constitutes connection of an electric signal with the power amplifier 51. According to this example, a plurality of mounting boards 60, 61 and 62 are stacked one after another and provided for use.

The basic HBT used here is an HBT having, over a substrate made of a semi-insulating GaAs substrate, a sub-collector layer (Si concentration: 5×10¹⁸ cm⁻³, film thickness: 0.6 μm) made of an n type GaAs layer, a collector layer (Si concentration: 1×10¹⁶ cm⁻³, film thickness: 1.0 μm) made of an n type GaAs layer, a base layer (C concentration: 4×10¹⁹ cm⁻³, film thickness: 150 nm) made of a p type GaAs layer, an emitter layer (InP molar ratio: 0.5, Si concentration: 3×10¹⁷ cm⁻³, film thickness: 30 nm) made of an n type IgGaP layer, a semiconductor layer (Si concentration: 3×10¹⁷ cm⁻³, film thickness: 90 nm) made of an n type GaAs layer, a high concentration semiconductor layer (Si concentration: 3×10¹¹ cm⁻³, film thickness: 30 nm) made of an n⁺ type GaAs layer, a ballast resistor layer (AlAs molar ratio: 0.33, Si concentration: 1×10¹⁷ cm⁻³, film thickness: 120 nm) made of an n type AlGaAs layer, a contact layer (Si concentration: 1×10¹⁹ cm⁻³, film thickness: 50 nm) made of an n type GaAs layer, and a contact layer (InAs molar ratio: 0.5, Si concentration: 1×10¹⁹ cm⁻³, film thickness: 50 nm) made of an n type InGaAs layer. The above-described HBT can satisfy both thermal stability and reliability and has improved electrostatic breakdown voltage. The power amplifier equipped with the above-described HBT is suited for a power amplifier module 63 which needs high power-high frequency operation and improved reliability.

The inventions made by the present inventors were described specifically based on some embodiments. The present invention is however not limited to these embodiments, but it is needless to say that the invention can be modified in many ways without departing from the scope of the invention.

For example, in the above-described embodiments, a compound semiconductor GaAs is used as a material for a substrate, but a compound semiconductor InP (indium phosphide) can also be used instead.

The present invention is widely utilized by the manufacturers of semiconductor devices.

1. A semiconductor device comprising a bipolar transistor made of a compound semiconductor,
wherein the bipolar transistor comprises:
a substrate;
a collector layer formed over the main surface of the substrate;
a base layer formed over the collector layer;
an emitter layer formed over the base layer and made of an InGaP layer;
a collector electrode electrically connected to the collector layer;
a base electrode electrically connected to the base layer;
an emitter mesa layer formed over the emitter layer and electrically connected to the emitter layer; and
an emitter electrode electrically connected to the emitter mesa layer;
wherein the emitter mesa layer comprises:
a first semiconductor layer;
a second semiconductor layer formed over the first semiconductor layer;
a ballast resistor layer formed over the second semiconductor layer and made of a semiconductor layer having a greater specific resistance than that of the second semiconductor layer; and
wherein the second semiconductor layer has a carrier concentration at least equal to that of the first semiconductor layer.

2. A semiconductor device according to claim 1,
wherein the second semiconductor layer is thinner than the first semiconductor layer.

3. A semiconductor device according to claim 1,
wherein the first semiconductor layer is made of a GaAs layer, and
the second semiconductor layer is made of a GaAs layer.

4. A semiconductor device according to claim 3,
wherein the ballast resistor layer is made of any one of an AlGaAs layer, AlInAs layer and GaInAsP layer.

5. A semiconductor device comprising a bipolar transistor made of a compound semiconductor,
wherein the bipolar transistor comprises:
a substrate;
a collector layer formed over the main surface of the substrate;
a base layer formed over the collector layer;
an emitter layer formed over the base layer and made of an InGaP layer;
a collector electrode electrically connected to the collector layer;
a base electrode electrically connected to the base layer;
an emitter mesa layer formed over the emitter layer and electrically connected to the emitter layer; and
an emitter electrode electrically connected to the emitter mesa layer;
wherein the emitter mesa layer comprises:
a first semiconductor layer made of a GaAs layer; and
a ballast resistor layer formed over the first semiconductor layer and made of a semiconductor layer having a greater specific resistance than that of the first semiconductor layer; and
wherein in a plane parallel to the main surface of the substrate, the length of the emitter mesa layer in the [01-1] direction of the substrate is greater than that in the [011] direction of the substrate.

6. A semiconductor device comprising a bipolar transistor made of a compound semiconductor,
wherein the bipolar transistor comprises:
a substrate;
a collector layer formed over the main surface of the substrate;
a base layer formed over the collector layer;
an emitter layer formed over the base layer and made of an InGaP layer;
a collector electrode electrically connected to the collector layer;
a base electrode electrically connected to the base layer;
an emitter mesa layer formed over the emitter layer and electrically connected to the emitter layer; and
an emitter electrode electrically connected to the emitter mesa layer;
wherein the emitter mesa layer comprises:
a first semiconductor layer made of a GaAs layer; and
a ballast resistor layer formed over the first semiconductor layer and made of a semiconductor layer having a greater specific resistance than that of the first semiconductor layer; and
wherein the side surface portions of the cross-section of the emitter mesa layer are formed into a forward tapered shape.

7. A semiconductor device according to claim 5,
wherein the ballast resistor layer is made of any one of an AlGaAs layer, AlInAs layer and GaInAsP layer.

8-17. (canceled)
